(19) United States
(12) Patent Application Publication
(10) Pub. No.: US 2012/0325139 A1
(43) Pub. Date: Dec. 27, 2012

(54) EPTAXIAL SUBSTRATE, METHOD FOR MAKING THE SAME AND METHOD FOR GROWING EPITAXIAL LAYER USING THE SAME

(75) Inventors: YANG WEI, Beijing (CN); SHOU-SHAN FAN, Beijing (CN)

(73) Assignees: HON HAI PRECISION INDUSTRY CO., LTD., Tu-Cheng (TW); TSINGHUA UNIVERSITY, Beijing (CN)

(21) Appl. No.: 13/337,017

(22) Filed: Dec. 23, 2011

(30) Foreign Application Priority Data
Jun. 24, 2011 (CN) 201110172964.0

(51) Int. Cl. C30B 25/04; C30B 23/04; B32B 38/00; B32B 3/00; B32B 3/24

(52) U.S. Cl. 117/95; 428/166; 156/292; 216/7; 117/106

(57) ABSTRACT

An epitaxial substrate is provided, the epitaxial substrate is used to grow epitaxial layer. The epitaxial substrate includes a base having a number of grooves to form a patterned epitaxial growth surface. The patterned epitaxial growth surface is referred as an epitaxial growth surface. A carbon nanotube layer covers on the epitaxial growth surface, and the carbon nanotube layer corresponding to the grooves is suspended on the epitaxial substrate.

### CROSS-REFERENCE TO RELATED APPLICATIONS

This application claims all benefits accruing under 35 U.S.C. §119 from China Patent Application: Application No. 201110172964.0, filed on Jun. 24, 2011 in the China Intellectual Property Office, disclosure of which are incorporated herein by reference.

### BACKGROUND

1. Technical Field

The present disclosure relates to an epitaxial substrate, a method for making the same and the application thereof.

2. Description of Related Art

Light emitting devices such as light emitting diodes (LEDs) based upon group III-V nitride semiconductors such as gallium nitride (GaN) have been put into practice.

Since wide GaN substrate cannot be produced, the LEDs have been produced upon a heteroepitaxial substrate such as sapphire. The use of sapphire substrate is problematic due to lattice mismatch and thermal expansion mismatch between GaN and the sapphire substrate. One consequence of thermal expansion mismatch is bowing of the GaN/sapphire substrate structure, which leads in turn to cracking and difficulty in fabricating devices with small feature sizes. A method for solving the problem is forming a plurality of grooves on surface of the sapphire substrate by lithography or etching. However, the process of lithography and etching are complex, high cost, and will pollute the sapphire substrate.

What is needed, therefore, is to provide an epitaxial method for solving the problem discussed above.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a flowchart of one embodiment of a method for making an epitaxial substrate.

FIG. 2 is a flowchart of one embodiment of a method for making a patterned base.

FIG. 3 is a schematic view of the patterned base in the method of FIG. 2.

FIG. 4 is a Scanning Electron Microscope (SEM) image of a drawn carbon nanotube film in the method of FIG. 1.

FIG. 5 is a schematic structural view of a carbon nanotube segment of the drawn carbon nanotube film of FIG. 4.

FIG. 6 is an SEM image of overlapped drawn carbon nanotube films.

FIG. 7 is an SEM image of an untwisted carbon nanotube wire.

FIG. 8 is an SEM image of a twisted carbon nanotube wire.

FIG. 9 is a schematic view of one embodiment of the epitaxial substrate fabricated according to the method of FIG. 1.

FIG. 10 is a flowchart of a method for growing an epitaxial layer on the epitaxial substrate.

FIG. 11 is a flowchart of another embodiment of a method for making an epitaxial substrate.

FIG. 12 is a schematic view of one embodiment of the epitaxial substrate fabricated according to the method of FIG. 11.

FIG. 13 is a flowchart of a method for growing an epitaxial layer on the epitaxial substrate of FIG. 12.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

References will now be made to the drawings to describe, in detail, various embodiments of the present epitaxial substrates and methods for making the same.

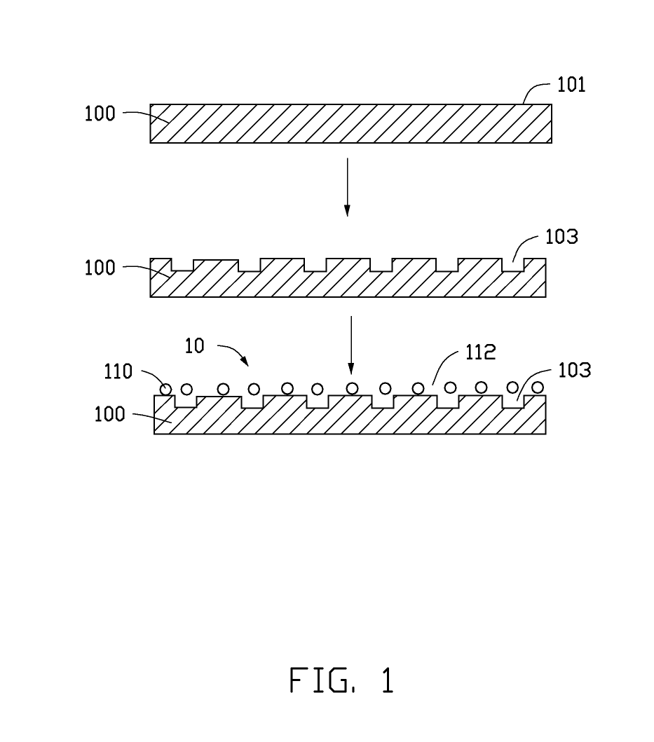

Referring to FIG. 1, a method for making an epitaxial substrate 10 of one embodiment includes following steps:

(S11) providing a base 100 having an epitaxial growth surface 101;

(S12) etching the epitaxial growth surface 101 to form a patterned surface; and

(S13) placing a carbon nanotube layer 110 on patterned surface.

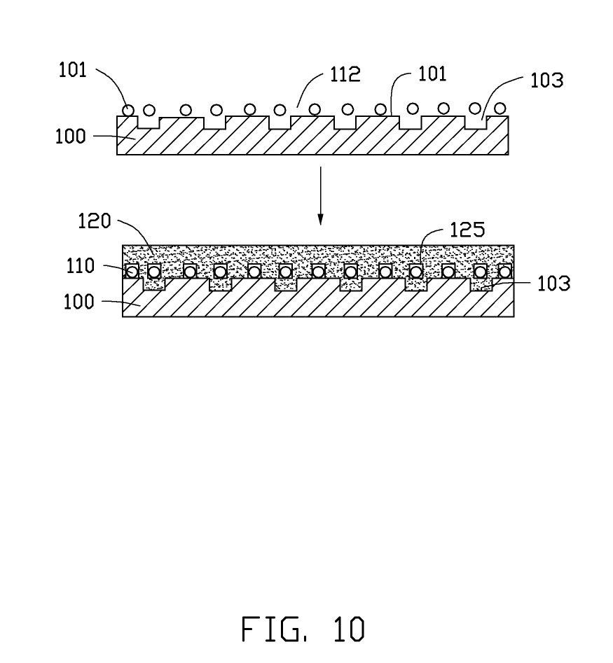

In step (S11), the epitaxial growth surface 101 is used to grow an epitaxial layer 120 as shown in FIG. 10. The epitaxial growth surface 101 is a very smooth surface. Oxygen and carbon are removed from the surface. The base 100 can be a single layer structure or a multiple layer structure. If the base 100 is a single layer structure, the base 100 can be a single-crystal structure. The single-crystal structure includes a crystal face which is used as the epitaxial growth surface 101. The material of the base 100 can be SOI (Silicon on insulator), LiGaO₂, LiAlO₂, Al₂O₃, Si, GaAs, GaN, GaSb, InN, InP, InAs, InSb, AlP, AlAs, AlSb, AlN, GaP, SiC, SiGe, GaMnAs, GaAlAs, GaInAs, GaAlN, GaInN, AlInN, GaAsP, InGaN, AlGaInN, AlGaInP, GaP:Zn or GaP:N. The material of the base 100 is not limited, as long as the base 100 has an epitaxial growth surface 101 on which the epitaxial layer 120 can grow. If the base 100 is a multiple layer structure, the base 100 should include at least one layer of the single-crystal structure mentioned previously. The material of the base 100 can be selected according to the epitaxial layer 120. In one embodiment, the lattice constant and thermal expansion coefficient of the base 100 is similar to the epitaxial layer 120 thereof in order to improve the quality of the epitaxial layer 120. In another embodiment, the material of the base 100 is sapphire. The thickness and the shape of the base 100 are arbitrary and can be selected according to need.

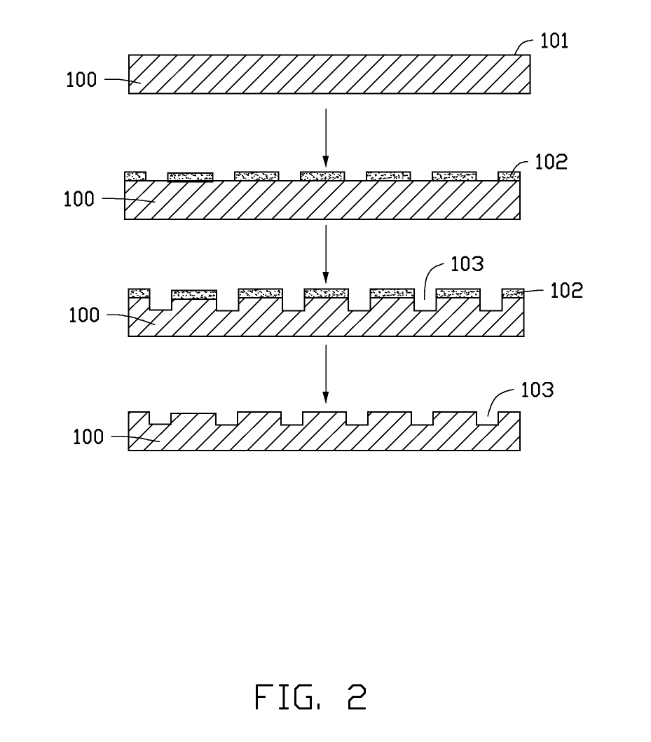

In step (S12), the epitaxial growth surface 101 can be etched via a method of wet etching or dry etching. Also referring to FIG. 2, the epitaxial growth surface 101 is etched via the wet etching method in one embodiment. The method includes following steps:

(S121) placing a patterned mask layer 102 on the epitaxial growth surface 101;

(S122) etching the epitaxial growth surface 101 to form a patterned surface; and

(S123) removing the mask layer 102.

In step (S121), the material of the mask layer 102 can be selected according to need, such as silicon dioxide, silicon nitride, silicon oxynitride, or titanium dioxide. The mask layer 102 can protect one part of the base 100 which is sheltered by the mask layer 102 from being corrupted by the solution. In one embodiment, the mask layer 102 is formed by following steps:

(S1211) depositing a silicon dioxide film on the epitaxial growth surface 101; and

(S1212) etching the silicon dioxide film via the lithography method to form a patterned mask layer 102.

In step (S1211), the silicon dioxide film can be deposited via the CVD method. The thickness of the silicon dioxide ranges from about 0.3 micrometer to about 2 micrometer.

In step (S1212), the silicon dioxide film is etched by following steps:

first, placing a photo resist on the silicon dioxide film;

second, exposing and developing the photo resist to form a patterned photo resist; and

third, etching the silicon dioxide film with a solution composed of HF₄ and the NH₄F to form the patterned mask layer 102.

The pattern of the mask layer 102 is arbitrary and can be selected according to need. The pattern can be an array which is composed of a plurality of units. The shape of the unit can be round, rectangle, hexagonal, diamond, triangle or irregular shape or any combinations of them. In one embodiment, the shape of the unit is rectangle. The rectangles are parallel with each other and spaced in a certain interval. The distance between the two adjacent units ranges from about 1 μm to about 20 μm. The width of the rectangle ranges from about 1 μm to about 50 μm.

In step (S122), the epitaxial growth surface 101 is etched by a solution comprising sulfuric acid and phosphoric acid. A first part of the epitaxial growth surface 101 which is sheltered by the mask layer 102 will be retained, and a second part of the epitaxial growth surface 101 which is exposed from the mask layer 102 will be dissolved in the solution. Thus the epitaxial growth surface 101 is patterned. The volume ratio between the sulfuric acid and the phosphoric acid ranges from about 1:3 to about 3:1. The etching temperature ranges from about 300° C. to about 500° C., and the etching time ranges from about 30 seconds to about 30 minutes. The etching time can be selected according to the etching depth.

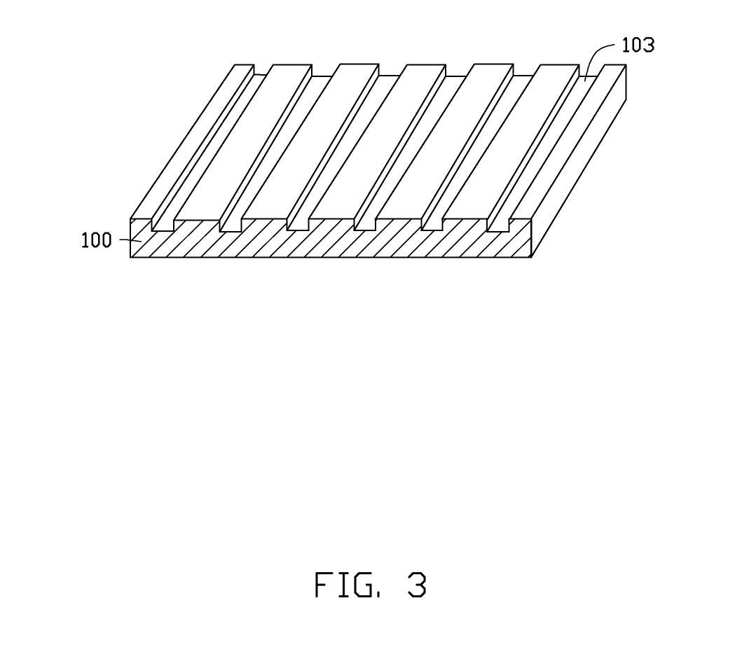

Also referring to FIG. 3, the pattern of the patterned base 100 is similar to that of the mask layer 102. In one embodiment, the base 100 defines a plurality of grooves 103 parallel with each other on the epitaxial growth surface 101. The grooves 103 are depressed from the epitaxial growth surface 101 into the base 100. The grooves 103 extend along the same direction. On the direction perpendicular with the extending direction of the grooves 103, the grooves 103 are spaced from each other with an interval. The interval between the two adjacent grooves 103 can be the same. The width of the grooves 103 ranges from about 1 μm to about 50 μm, and the interval between the two adjacent grooves 103 ranges from about 1 μm to about 20 μm. The depth of the grooves 103 ranges from about 0.1 μm to about 1 μm. The depth of the grooves 103 can be selected according to need. Furthermore, the depth of the grooves 103 can be same.

In step (S123), the mask layer 102 can be removed by dissolving in a HF₄ solution. Furthermore, the surface of the base 100 can be washed with de-ionized water to remove the residual impurity such as HF₄.

In step (S13), the carbon nanotube layer 110 can be formed by directly placing a carbon nanotube film on the epitaxial growth surface 101. The carbon nanotube layer 110 covers the epitaxial growth surface 101. The carbon nanotube layer 110 can be an ordered carbon nanotube structure or a disordered carbon nanotube structure. In one embodiment, the ordered carbon nanotube structure includes a plurality of carbon nanotubes extending along the same direction. The carbon nanotubes in the ordered carbon nanotube structure can also be arranged to extend along the crystallographic orientation of the substrate 100 or along a direction which forms an angle with the crystallographic orientation of the substrate 100. The carbon nanotube layer 110 includes a first part and a second part. The first part covers the epitaxial growth surface 101 which located between the two adjacent grooves 103. The second portion is suspended above the grooves 103, and not contacts with the epitaxial growth surface 101. The carbon nanotube layer 110 is a continuous and integrated structure and includes a plurality of carbon nanotubes. The carbon nanotubes extend parallel with the surface of the carbon nanotube layer 110.

The carbon nanotube layer 110 includes a plurality of carbon nanotubes. The carbon nanotubes in the carbon nanotube layer 110 can be single-walled, double-walled, or multi-walled carbon nanotubes. The length and diameter of the carbon nanotubes can be selected according to need. The thickness of the carbon nanotube layer 110 can be in a range from about 1 nm to about 100 μm, for example 10 nm, 100 nm, 200 nm, 1 μm, 10 μm or 50 μm. The carbon nanotube layer 110 forms a pattern so that part of the epitaxial growth surface 101 can be exposed from the patterned carbon nanotube layer 110 after the carbon nanotube layer 110 is placed on the epitaxial growth surface 101. Thus, the epitaxial layer 120 can grow from the exposed epitaxial growth surface 101. The carbon nanotube layer 110 is a patterned structure.

The term “patterned structure” means that the carbon nanotube layer 110 defines a plurality of apertures 112 penetrating the carbon nanotube layer 110 perpendicular to the surface of the carbon nanotube layer 110. The apertures 112 can be micro-holes formed by the adjacent carbon nanotubes. The apertures 112 can also be gaps formed by the adjacent carbon nanotubes aligned parallel with each other along the axial direction of the carbon nanotubes. If the apertures 112 are micro-holes, the diameter of the micro-hole range from about 10 nm to about 500 μm. If the apertures 112 are gaps, the average width of the gap ranges from about 10 nm to about 500 nm. The carbon nanotube layer 110 can have both micro-holes and gaps at the same time. The diameter of the micro-hole and the width of the gap can be different. In one embodiment, the apertures 112 uniformly distribute in the carbon nanotube layer 110.

Both the diameter of the micro-hole and the width of the gap are defined as “the size of the apertures” in the following description. The size of the apertures 112 range from about 10 nm to about 500 μm, such as 1 micrometer, 10 micrometer 80 μm, or 120 μm. The smaller the size of the apertures 112, the fewer dislocations exist in the process of growing the epitaxial layer, and the higher the quality of epitaxial layer 120. In one embodiment, the size of the apertures 112 range from about 10 nm to about 10 μm. Furthermore, the duty cycle of the carbon nanotube layer 110 ranges from about 1:100 to about 100:1 such as 1:10, 1:2, 1:4, 4:1, 2:1, or 10:1. “Duty cycle” is defined as the area ratio between the epitaxial growth surface 101 which is covered by carbon nanotubes and the exposed surface which is exposed via the apertures 112. In one embodiment, the duty cycle of the carbon nanotube layer 110 ranges from about 1:4 to about 4:1.

The carbon nanotubes of the carbon nanotube layer 110 can be arranged orderly to form an ordered carbon nanotube structure or disorderly to form a disordered carbon nanotube structure. The term ‘disordered carbon nanotube structure’ includes, but is not limited to, to a structure where the carbon nanotubes are arranged along many different directions, and the aligning directions of the carbon nanotubes are random. The number of the carbon nanotubes arranged along each different direction can be almost the same (e.g. uniformly disordered). The disordered carbon nanotube structure can be isotropic. The carbon nanotubes in the disordered carbon nanotube structure can be entangled with each other. The term ‘ordered carbon nanotube structure’ includes, but is not limited to, to a structure where the carbon nanotubes are arranged in a consistently systematic manner, e.g., the carbon nanotubes are arranged approximately along a same direction and/or have two or more sections within each of which the carbon nanotubes are arranged approximately along a same direction (different sections can have different directions).

In one embodiment, the carbon nanotubes in the carbon nanotube layer 110 are arranged to extend along the direction substantially parallel to the surface of the carbon nanotube layer 110 in order to obtain a better pattern and greater light transmission. After being placed on the epitaxial growth surface 101, the carbon nanotubes in the carbon nanotube layer 110 are arranged to extend along the direction substantially parallel to the epitaxial growth surface 101. In one embodiment, all the carbon nanotubes in the carbon nanotube layer 110 are arranged to extend along the same direction. In another embodiment, part of the carbon nanotubes in the carbon nanotube layer 110 are arranged to extend along a first direction, and the other part of the carbon nanotubes in the carbon nanotube layer 110 are arranged to extend along a second direction. The first direction is perpendicular to the second direction. Also the carbon nanotubes in the ordered carbon nanotube structure can be arranged to extend along the crystallographic orientation of the base 100 or along a direction which forms an angle with the crystallographic orientation of the base 100.

The carbon nanotube layer 110 can be formed on the epitaxial growth surface 101 by chemical vapor deposition (CVD), transfer printing a preformed carbon nanotube film, filtering and depositing a carbon nanotube suspension. However, all of the above described methods need an assistant support. In one embodiment, the carbon nanotube layer 110 is a free-standing structure and can be drawn from a carbon nanotube array. The term “free-standing structure” means that the carbon nanotube layer 110 can sustain the weight of itself when it is hoisted by a portion thereof without any significant damage to its structural integrity. Thus, the carbon nanotube layer 110 can be suspended by two spaced supports. The free-standing carbon nanotube layer 110 can be laid on the epitaxial growth surface 101 directly and easily.

The carbon nanotube layer 110 can be a substantially pure structure of the carbon nanotubes, with few impurities and chemical functional groups. The carbon nanotube layer 110 can be a composite including a carbon nanotube matrix and some non-carbon nanotube materials. The non-carbon nanotube materials can be graphite, graphene, silicon carbide, boron nitride, silicon nitride, silicon dioxide, diamond, or amorphous carbon. Also, the non-carbon nanotube materials can be metal carbides, metal oxides, or metal nitrides. The non-carbon nanotube materials can be coated on the carbon nanotubes of the carbon nanotube layer 110 or filled in the aperture 112. In one embodiment, the non-carbon nanotube materials are coated on the carbon nanotubes of the carbon nanotube layer 110 so the carbon nanotubes have greater diameter and the apertures 112 have smaller size. The non-carbon nanotube materials can be deposited on the carbon nanotubes of the carbon nanotube layer 110 by CVD or physical vapor deposition (PVD), such as sputtering.

Furthermore, the carbon nanotube layer 110 can be treated with an organic solvent after being placed on the epitaxial growth surface 101 so the carbon nanotube layer 110 can be attached on the epitaxial growth surface 101 firmly. Specifically, the organic solvent can be applied to entire surface of the carbon nanotube layer 110 or the entire carbon nanotube layer 110 can be immerged in an organic solvent. The organic solvent can be volatile, such as ethanol, methanol, acetone, dichloroethane, chloroform, or mixtures thereof. In one embodiment, the organic solvent is ethanol.

The carbon nanotube layer 110 can include at least one carbon nanotube film, at least one carbon nanotube wire, or combination thereof. In one embodiment, the carbon nanotube layer 110 can include a single carbon nanotube film or two or more stacked carbon nanotube films. Thus, the thickness of the carbon nanotube layer 110 can be controlled by controlling the number of the stacked carbon nanotube films. The number of the stacked carbon nanotube films can be in a range from about 2 to about 100, for example 10, 30, or 50. In one embodiment, the carbon nanotube layer 110 can include a layer of parallel and spaced carbon nanotube wires. Also, the carbon nanotube layer 110 can include a plurality of carbon nanotube wires crossed, or weaved together to form a carbon nanotube net. The distance between two adjacent parallel and spaced carbon nanotube wires can be in a range from about 0.1 μm to about 200 μm. In one embodiment, the distance between two adjacent parallel and spaced carbon nanotube wires can be in a range from about 10 μm to about 100 μm. The gap between two adjacent substantially parallel carbon nanotube wires is defined as the aperture 112. The size of the aperture 112 can be controlled by controlling the distance between two adjacent parallel and spaced carbon nanotube wires. The length of the gap between two adjacent parallel carbon nanotube wires can be equal to the length of the carbon nanotube wire. It is understood that any carbon nanotube structure described can be used with all embodiments.

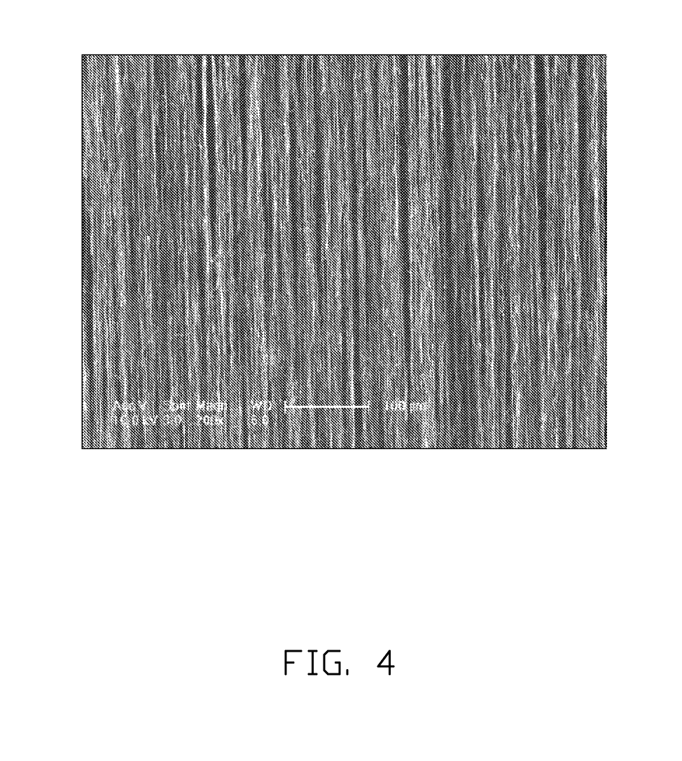

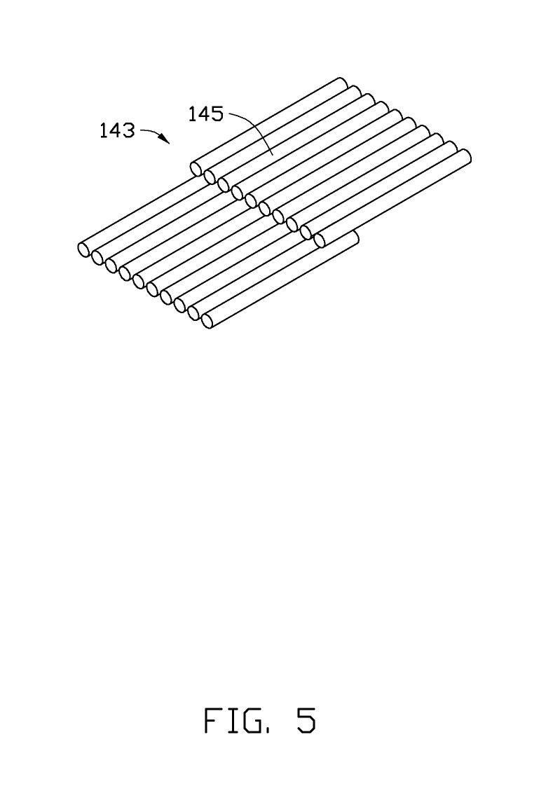

In one embodiment, the carbon nanotube layer 110 includes at least one drawn carbon nanotube film. A drawn carbon nanotube film can be drawn from a carbon nanotube array that is able to have a film drawn therefrom. The drawn carbon nanotube film includes a plurality of successive and oriented carbon nanotubes joined end-to-end by van der Waals attractive force therebetween. The drawn carbon nanotube film is a free-standing film. Referring to FIGS. 4 and 5, each drawn carbon nanotube film includes a plurality of successively oriented carbon nanotube segments 143 joined end-to-end by van der Waals attractive force therebetween. Each carbon nanotube segment 143 includes a plurality of carbon nanotubes 145 parallel to each other, and combined by van der Waals attractive force therebetween. As can be seen in FIG. 4, some variations can occur in the drawn carbon nanotube film. The carbon nanotubes 145 in the drawn carbon nanotube film are oriented along a preferred orientation. The drawn carbon nanotube film can be treated with an organic solvent to increase the mechanical strength and toughness and reduce the coefficient of friction of the drawn carbon nanotube film. A thickness of the drawn carbon nanotube film can range from about 0.5 nm to about 100 μm. The drawn carbon nanotube film can be attached to the epitaxial growth surface 101 directly.

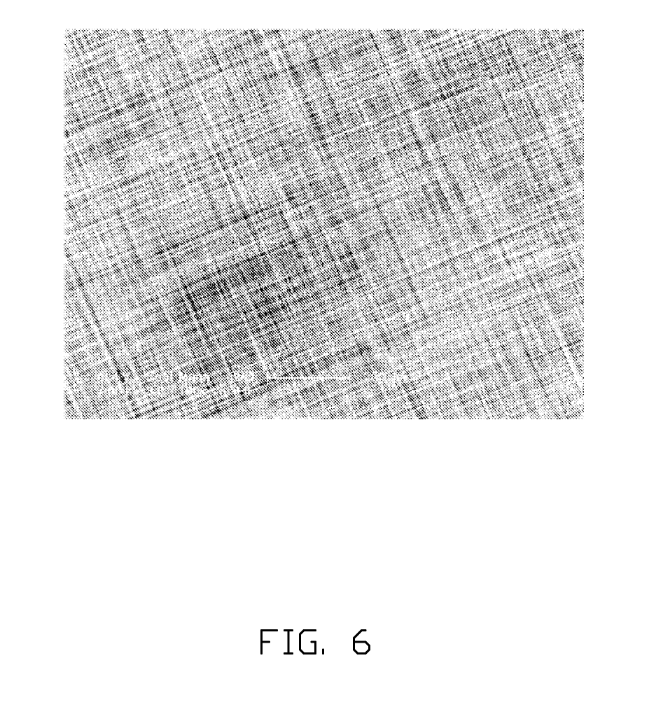

The carbon nanotube layer 110 can include at least two stacked drawn carbon nanotube films. In other embodiments, the carbon nanotube layer 110 can include two or more coplanar carbon nanotube films, and can include layers of coplanar carbon nanotube films. Additionally, when the carbon nanotubes in the carbon nanotube film are aligned along one preferred orientation (e.g., the drawn carbon nanotube film), an angle can exist between the orientation of carbon nanotubes in adjacent films, whether stacked or adjacent. Adjacent carbon nanotube films can be combined by only the van der Waals attractive force therebetween. An angle between the aligned directions of the carbon nanotubes in two adjacent carbon nanotube films can range from about 0 degrees to about 90 degrees. When the angle between the aligned directions of the carbon nanotubes in adjacent stacked drawn carbon nanotube films is larger than 0 degrees, a plurality of micro-holes is defined by the carbon nanotube layer 110. Referring to FIG. 6, the carbon nanotube layer 110 is shown with the angle between the aligned directions of the carbon nanotubes in adjacent stacked drawn carbon nanotube films is 90 degrees. Stacking the carbon nanotube films will also add to the structural integrity of the carbon nanotube layer 110.

A step of heating the drawn carbon nanotube film can be performed to decrease the thickness of the drawn carbon nanotube film. The drawn carbon nanotube film can be partially heated by a laser or microwave. The thickness of the drawn carbon nanotube film can be reduced because some of the carbon nanotubes will be oxidized. In one embodiment, the drawn carbon nanotube film is irradiated by a laser device in an atmosphere comprising of oxygen therein. The power density of the laser is greater than 0.1×10⁴ W/m². The drawn carbon nanotube film can be heated by fixing the drawn carbon nanotube film and moving the laser device at an even/uniform speed to irradiate the drawn carbon nanotube film. When the laser irradiates the drawn carbon nanotube film, the laser is focused on the surface of drawn carbon nanotube film to form a laser spot. The diameter of the laser spot ranges from about 1 micron to about 5 millimeters. In one embodiment, the laser device is carbon dioxide laser device. The power of the laser device is 30 watts. The wavelength of the laser is 10.6 μm. The diameter of the laser spot is 3 mm. The velocity of the laser movement is less than 10 m/s. The power density of the laser is 0.053×10¹² W/m².

In another embodiment, the carbon nanotube layer 110 can include at least a pressed carbon nanotube film. The pressed carbon nanotube film can be a free-standing carbon nanotube film. The carbon nanotubes in the pressed carbon nanotube film are arranged along a same direction or arranged along different directions. The carbon nanotubes in the pressed carbon nanotube film can rest upon each other. Adjacent carbon nanotubes are attracted to each other and combined by van der Waals attractive force. An angle between a primary alignment direction of the carbon nanotubes and a surface of the pressed carbon nanotube film is 0 degrees to approximately 15 degrees. The greater the pressure applied, the smaller the angle formed. When the carbon nanotubes in the pressed carbon nanotube film are arranged along different directions, the carbon nanotube layer 110 can be isotropic.

In another embodiment, the carbon nanotube layer 110 includes a flocculated carbon nanotube film. The flocculated carbon nanotube film can include a plurality of long, curved, disordered carbon nanotubes entangled with each other. Further, the flocculated carbon nanotube film can be isotropic. The carbon nanotubes can be substantially uniformly dispersed in the carbon nanotube film. Adjacent carbon nanotubes are acted upon by van der Waals attractive force to form an entangled structure with micro-holes defined therein. It is understood that the flocculated carbon nanotube film is very porous. Sizes of the micro-holes can be less than 10 μm. The porous nature of the flocculated carbon nanotube film will increase specific surface area of the carbon nanotube layer 110. Further, due to the carbon nanotubes in the carbon nanotube layer 110 being entangled with each other, the carbon nanotube layer 110 employing the flocculated carbon nanotube film has excellent durability, and can be fashioned into desired shapes with a low risk to the integrity of the carbon nanotube layer 110. The flocculated carbon nanotube film, in some embodiments, is free standing due to the carbon nanotubes being entangled and adhered together by van der Waals attractive force therebetween.

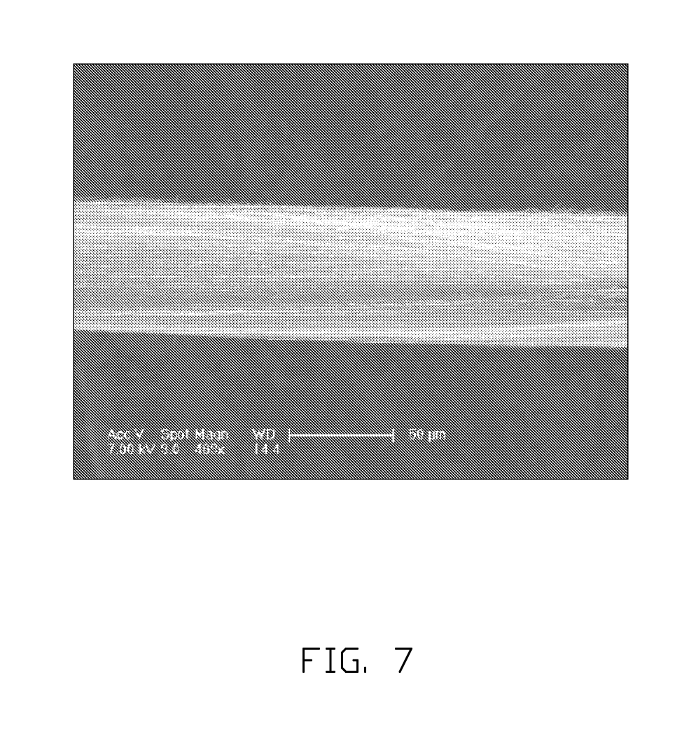

The carbon nanotube wire can be untwisted or twisted. Treating the drawn carbon nanotube film with a volatile organic solvent can form the untwisted carbon nanotube wire. Specifically, the organic solvent is applied to soak the entire surface of the drawn carbon nanotube film. During the soaking, adjacent parallel carbon nanotubes in the drawn carbon nanotube film will bundle together, due to the surface tension of the organic solvent as it volatilizes, and thus, the drawn carbon nanotube film will be shrunk into untwisted carbon nanotube wire. Referring to FIG. 7, the untwisted carbon nanotube wire includes a plurality of carbon nanotubes substantially oriented along a same direction (i.e., a direction along the length of the untwisted carbon nanotube wire). The carbon nanotubes are parallel to the axis of the untwisted carbon nanotube wire. More specifically, the untwisted carbon nanotube wire includes a plurality of successive carbon nanotube segments joined end to end by van der Waals attractive force therebetween. Each carbon nanotube segment includes a plurality of carbon nanotubes substantially parallel to each other, and combined by van der Waals attractive force therebetween. The carbon nanotube segments can vary in width, thickness, uniformity and shape. Length of the untwisted carbon nanotube wire can be arbitrarily set as desired. A diameter of the untwisted carbon nanotube wire ranges from about 0.5 nm to about 100 μm.

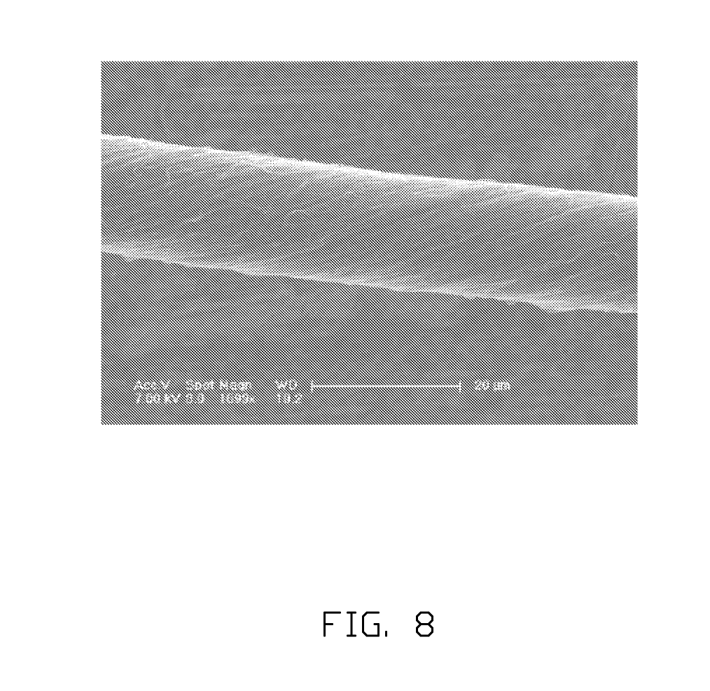

The twisted carbon nanotube wire can be formed by twisting a drawn carbon nanotube film using a mechanical force to turn the two ends of the drawn carbon nanotube film in opposite directions. Referring to FIG. 8, the twisted carbon nanotube wire includes a plurality of carbon nanotubes helically oriented around an axial direction of the twisted carbon nanotube wire. More specifically, the twisted carbon nanotube wire includes a plurality of successive carbon nanotube segments joined end to end by van der Waals attractive force therebetween. Each carbon nanotube segment includes a plurality of carbon nanotubes parallel to each other, and combined by van der Waals attractive force therebetween. Length of the carbon nanotube wire can be set as desired. A diameter of the twisted carbon nanotube wire can be from about 0.5 nm to about 100 μm. Further, the twisted carbon nanotube wire can be treated with a volatile organic solvent after being twisted. After being soaked by the organic solvent, the adjacent paralleled carbon nanotubes in the twisted carbon nanotube wire will bundle together, due to the surface tension of the organic solvent when the organic solvent volatilizing. The specific surface area of the twisted carbon nanotube wire will decrease, while the density and strength of the twisted carbon nanotube wire will be increased.

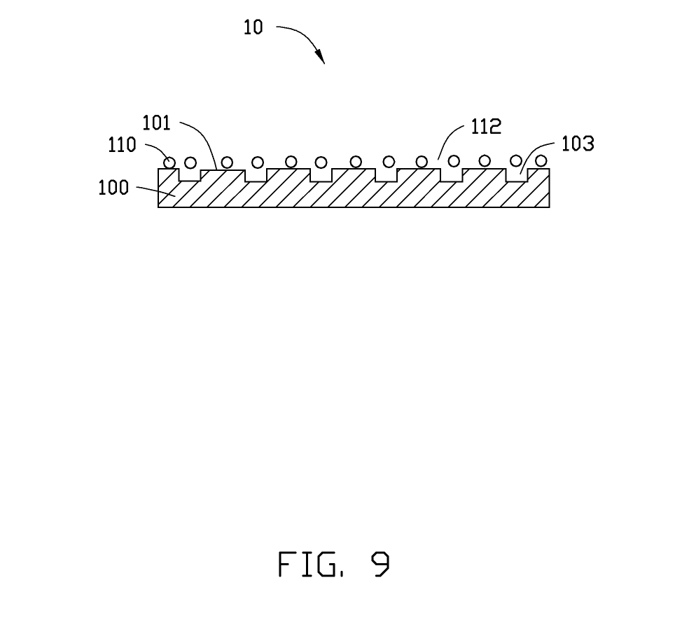

Referring to FIG. 9, an epitaxial substrate 10 provided in one embodiment includes a base 100 and a carbon nanotube layer 110. The base 100 includes an epitaxial growth surface 101. The base 100 defines a plurality of grooves 103 on the epitaxial growth surface 101. The carbon nanotube layer 110 covers the epitaxial growth surface 101. A part of the carbon nanotube layer 110 which corresponds with the grooves 103 is suspended.

The grooves 103 are intersected or are parallel with each other. The carbon nanotube layer 110 includes a plurality of carbon nanotubes connected end to end by van der Waals force. The carbon nanotubes substantially extend along the same direction. The extending direction of the carbon nanotubes is parallel with the surface of the epitaxial growth surface 101. The extending direction of the carbon nanotubes can be parallel with, perpendicular with or intersected with the extending direction of the grooves 103. The carbon nanotube layer 110 covers the entire epitaxial growth surface 101. The part of the carbon nanotube layer 110 which is suspended above the grooves 103 is not in contact with the epitaxial growth surface 101.

The epitaxial substrate 10 and the method for making the same have following advantages. First, the carbon nanotube layer is a continuous and free-standing structure, thus the carbon nanotube layer can be directly placed on the epitaxial growth surface, and the process is simple. Second, the base is a patterned structure, thus the lattice defects in making epitaxial layer will be reduced. Third, because of the existence of the carbon nanotube layer, the epitaxial layer can only grow through the apertures of the carbon nanotube layer, thus the lattice defects will be reduced and the quality of the epitaxial layer will be improved. Fourth, the base defines a plurality of grooves on the epitaxial growth surface, and the carbon nanotube layer is located thereon, thus the contact surface between the epitaxial layer and the base is reduced, and the stress between them will be reduced.

Referring to FIG. 10, a method for growing an epitaxial layer 120 using the epitaxial substrate 10 includes following steps:

(S14) providing an epitaxial substrate 10; and

(S15) growing an epitaxial layer 120 on the epitaxial growth surface 101.

In step (S14), the epitaxial substrate 10 includes a base 100 and a carbon nanotube layer 110. The base 100 defines a plurality of grooves 103 on a surface. The base 100 includes a patterned surface referred as the epitaxial growth surface 101. The carbon nanotube layer 110 covers the entire epitaxial growth surface 101. The carbon nanotube layer 110 includes a first part and a second part. The first part of the carbon nanotube layer 110 contacts and covers on one part surface of the base 100 which is located between two adjacent grooves 103. The second part of the carbon nanotube layer 110 which corresponds with the grooves 103 is suspended on the grooves 103.

In step (S15), the epitaxial layer 120 can be grown by a method such as molecular beam epitaxy (MBE), chemical beam epitaxy (CBE), reduced pressure epitaxy, low temperature epitaxy, select epitaxy, liquid phase deposition epitaxy (LPE), metal organic vapor phase epitaxy (MOVPE), ultra-high vacuum chemical vapor deposition (UHVCVD), hydride vapor phase epitaxy (HYPE), or metal organic chemical vapor deposition (MOCVD).

The epitaxial layer 120 is a single crystal layer grown on the epitaxial growth surface 101 by epitaxy growth. The material of the epitaxial layer 120 can be same as or different from the material of the base 100. When the epitaxial layer 120 and the base 100 have the same material, the epitaxial layer 120 is called homogeneous epitaxial layer. When the epitaxial layer 120 and the base 100 have different material, the epitaxial layer 120 is called heteroepitaxial epitaxial layer. The material of the epitaxial layer 120 can be semiconductor, metal or alloy. The semiconductor can be Si, GaAs, GaN, GaSb, InN, InP, InAs, InSb, AlP, AlAs, AlSb, AlN, GaP, SiC, SiGe, GaMnAs, GaAlAs, GaInAs, GaAlN, GaInN, AlInN, GaAsP, InGaN, AlGaInN, AlGaInP, GaP:Zn, or GaP:N. The metal can be aluminum, platinum, copper, or silver. The alloy can be MnGa, CoMnGa, or Co₂MnGa. The thickness of the epitaxial layer 120 can be prepared according to needed. The thickness of the epitaxial layer 120 can be in a range from about 100 nm to about 500 μm, for example 200 nm, 500 nm, 1 μm, 2 μm, 5 μm, 10 μm, 50 μm.

In step (S15), the epitaxial layer 120 is made by MOCVD, and the growth of the epitaxial layer 120 is heteroepitaxial growth. In the MOCVD, the nitrogen source gas is high-purity ammonia (NH₃), the carrier gas is hydrogen (H₂), the Ga source gas can be trimethyl gallium (TMGa) or triethyl gallium (TEGa), and the Si source gas is silane (SiH₄). The growth of the epitaxial layer 120 includes the following steps:

(S151) placing the epitaxial substrate 10 with the carbon nanotube layer 110 thereon into a reaction chamber and heating the epitaxial substrate 10 to 1100° C.˜1200° C., introducing the carrier gas and baking the epitaxial substrate 10 for about 200 seconds to about 1000 seconds;

(S152) cooling down the temperature to a range from about 500° C. to 650° C. in the carrier gas atmosphere, introducing the Ga source gas and the nitrogen source gas at the same time to grow the low-temperature GaN layer;

(S153) stopping introducing the Ga source gas in the carrier gas and nitrogen source gas atmosphere, increasing the temperature to a range from about 1100° C. to about 1200° C. and keeping for about 30 seconds to about 300 seconds;

(S154) keeping the temperature of the epitaxial substrate 10 in a range from about 1000° C. to about 1100° C., introducing the Ga source gas again and the Si source gas to grow the high quality epitaxial layer 120.

The growth of the epitaxial layer 120 includes following stages:

First stage, a plurality of epitaxial crystal nucleus forms on the entire exposed epitaxial growth surface 101, and the epitaxial crystal nucleus grows to a plurality of epitaxial crystal grains along the direction perpendicular the epitaxial growth surface 101;

Second stage, the plurality of epitaxial crystal grains grows to a continuous epitaxial film along the direction parallel to the epitaxial growth surface 101;

Third stage, the epitaxial film continuously grows along the direction perpendicular to the epitaxial growth surface 101 to form a high quality epitaxial film, the epitaxial growth grains, epitaxial film and the high-quality epitaxial film constitute the epitaxial layer 120.

In the first stage, because the carbon nanotube layer 110 is located on the epitaxial growth surface 101, the epitaxial crystal grains are grown from the exposed epitaxial growth surface 101 through the apertures 112. The process of epitaxial crystal grains which grow along the direction substantially perpendicular to the epitaxial growth surface 101 is called vertical epitaxial growth. The first part of the carbon nanotube layer 110 directly contacts and covers the epitaxial growth surface 101, the epitaxial crystal grains grow from the apertures 112 of the carbon nanotube layer 110. The second part of the carbon nanotube layer 110 is suspended on the grooves 103, thus the epitaxial crystal grains grow from the bottom of the grooves 103. While the crystal grains grow to the plane of the second part of the carbon nanotube layer 110, the crystal grains will grow out of the carbon nanotube layer 110 through the apertures 112.

In the second stage, the epitaxial crystal grains can grow along the direction parallel to the epitaxial growth surface 101. The epitaxial crystal grains are gradually joined together to form the epitaxial film to cover the carbon nanotube layer 110. During the growth process, the epitaxial crystal grains will grow around the carbon nanotubes, and then a plurality of holes 125 will be formed in the epitaxial layer 120 where the carbon nanotubes existed. The extending direction of the holes 125 is parallel to the orientated direction of the carbon nanotubes. The carbon nanotubes are located into the holes 125 and enclosed by the epitaxial layer 120 and the base 100. An inner wall of the holes 125 can be in contact with or spaced from the carbon nanotubes, which depends on the wetting property between the material of the epitaxial film and the carbon nanotubes. There is at least one carbon nanotube in each hole 125. The carbon nanotubes in the holes 125 are joined by van der Waals force to form the carbon nanotube layer 110. The pattern of the holes 125 correspond to the patterned carbon nanotube layer 110. The shape of the cross section of the holes 125 can be square, and a width of the holes 125 ranges from about 20 nm to about 200 nm. The plurality of holes 125 forms a patterned surface on the epitaxial layer 120. The patterned surface of the epitaxial layer 120 is similar to the carbon nanotube layer 110.

While the carbon nanotube layer 110 includes a carbon nanotube film or a plurality of intersecting carbon nanotube wires, the plurality of holes 125 is interconnected with each other to form a continuous network structure. The carbon nanotubes are also interconnected with each other to form a conductive structure. While the carbon nanotube layer 110 includes a plurality of carbon nanotube wires parallel to each other, the plurality of holes 125 are parallel to each other as well. The holes 125 are aligned with a certain interval, and the distance between the two adjacent holes 125 is substantially equal to the distance between the two adjacent carbon nanotube wires.

In the third stage, the epitaxial layer 120 covers the carbon nanotube layer 110, and contacts with the base 100 through the apertures 112. The epitaxial layer 120 is filled into the grooves 103. Due to the carbon nanotube layer 110 and the grooves 103, the lattice dislocation between the epitaxial crystal grains and the base 100 will be reduced during the growing process, thus the epitaxial layer 120 has less defects therein.

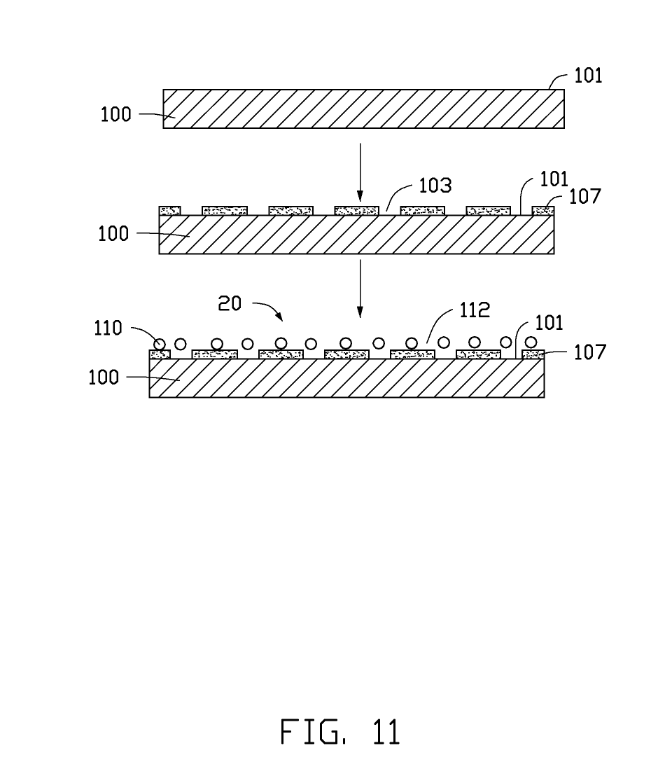

Referring to FIG. 11, a method for making an epitaxial substrate 20 according to another embodiment includes following steps:

(S21) proving a base 100 having an epitaxial growth surface 101;

(S22) forming a plurality of microstructures 107 on the epitaxial growth surface 101; and

(S23) placing a carbon nanotube layer 110 on the surface of the microstructures 107.

The method of making the epitaxial substrate 20 is similar to that of the epitaxial substrate 10.

In step (S22), the material of microstructure 107 can be the same as or different from the material of the base 100. The microstructure 107 can also be directly located on the epitaxial growth surface 101. In one embodiment, the method for making the microstructure 107 includes following steps:

(S221a) placing a layer-shaped structure (not shown) on the epitaxial growth surface 101; and

(S221b) forming a plurality of microstructures 107 by etching the layer-shaped structure.

In step (S221a), the material of the layer-shaped structure can be selected according to need, for example the silicon dioxide, silicon nitride, silicon oxynitride, or titanium dioxide. In one embodiment, the material is silicon dioxide.

In step (S221b), the layer-shaped structure is etched through the entire thickness of the layer-shaped structure to expose the epitaxial growth surface 101. The plurality of microstructures 107 forms a pattern which is arbitrary. In one embodiment, the plurality of microstructure 107 is bar-shaped and parallel with and spaced from each other. The width of the microstructure 107 ranges from about 1 μm to about 50 μm. The distance between the two adjacent microstructures 107 ranges from about 1 μm to about 20 μm. A groove 103 is defined between each of the two adjacent microstructures 107.

The microstructure 107 can also be made by epitaxial growth method via a carbon nanotube layer referred as a mask layer. In one embodiment, the method for making the microstructure 107 includes following steps:

(S222a) placing a carbon nanotube layer (not shown) on the epitaxial growth surface 101;

(S222b) growing a plurality of microstructures 107 on the epitaxial growth surface 101; and

(S222c) removing the carbon nanotube layer.

In step (S222a), the carbon nanotube layer is configured as the mask layer to grow the microstructure 107. The carbon nanotube layer can be an ordered carbon nanotube structure. The carbon nanotubes in the ordered carbon nanotube structure can also be arranged to extend along the crystallographic orientation of the base 100 or along a direction where an angle with the crystallographic orientation of the base 100 is formed. The structure of the second carbon nanotube layer is same as that of the carbon nanotube layer 110. The microstructures 107 can only grow from the apertures 112 of the carbon nanotube layer. The carbon nanotube layer includes the plurality of apertures 112, thus the carbon nanotube layer can be configured as the patterned mask layer. While the carbon nanotube layer is located on the epitaxial growth surface 101, the carbon nanotubes of the carbon nanotube layer are parallel to the epitaxial growth surface 101.

In step (S222b), a plurality of epitaxial grains grows on the epitaxial growth surface 101 to form the microstructures 107. The growth direction of the epitaxial grains is perpendicular to the epitaxial growth surface 101. The shape of the microstructures 107 is the same as the shape of the apertures 112. In one embodiment, the carbon nanotubes of the carbon nanotube layer are oriented substantially along the same direction, thus the shape of the microstructures 107 is in a shape of bar. The microstructures 107 are parallel with each other and spaced from each other. The microstructures 107 are oriented substantially along the same direction and parallel to the epitaxial growth surface 101. The oriented direction of the microstructures 107 is the same as the carbon nanotubes. The thickness of the microstructures 107 can be equal to or smaller than that of the carbon nanotube layer. Thus, the groove 103 is defined between the two adjacent microstructures 107.

In one embodiment, the carbon nanotube layer includes a plurality of carbon nanotube films intersected with each other or a plurality of carbon nanotube wires intersected with each other. The epitaxial grains grow from the apertures 112 to form a plurality of dot-like microstructures 107. The dot-like microstructures 107 are dispersed on the epitaxial growth surface 101. The maximum size of the dot-like microstructures 107 ranges from about 10 nm to about 10 μm.

The material of the microstructures 107 is arbitrary, and can be GaN, GaS and Cu₃P₂. The material of the microstructures 107 can be same as the base 100. In one embodiment, the material of the microstructures 107 is GaN.

In step (S222c), the carbon nanotube layer can be removed by plasma etching, ultrasonic oscillation, laser heating, or reaction chamber heating. In one embodiment, the carbon nanotube layer is removed by laser heating. The method of removing the carbon nanotube layer includes the following steps:

(c1) providing a laser device, irradiating the carbon nanotube layer with the laser transmitted by the laser device; and

(c2) scanning the carbon nanotube layer with the laser in an oxidized atmosphere.

The laser device can be solid lasers, liquid lasers, gas lasers, or semiconductor lasers. The power density of the laser is greater than 0.053×10¹² watt/m². The diameter of the light spot ranges from about 1 mm to about 5 mm. The irradiation time is less than 1.8 second. In one embodiment, the laser device is CO₂ laser, the power density is about 30 watt, the wavelength is about 10.6 μm and the diameter of the light spot is about 3 mm.

The carbon nanotubes on the epitaxial growth surface 101 can be ablated by the laser. The irradiation time of the laser can be controlled by controlling the moving speed of the laser relative to the carbon nanotube layer. The carbon nanotubes will be oxidized to CO₂. After the carbon nanotubes are removed, a plurality of microstructures 107 is formed on the epitaxial growth surface 101 and spaced from each other.

In step (S23), the carbon nanotube layer 110 is directly placed on the microstructure 107 and covers the microstructure 107. The carbon nanotube layer 110 includes a first part and a second part. The first part contacts and covers the surface of the microstructure 107, and the second part is suspended between the two adjacent microstructures 107 and spaced from the epitaxial growth surface 101. The extending direction of the carbon nanotubes is parallel to or intersected with that of the bar-shaped microstructure 107. In one embodiment, the extending direction of the carbon nanotubes is perpendicular with that of the microstructure 107, thus the lattice defects during the growth of epitaxial layer will be reduced. The carbon nanotube layer 110 defines a plurality of apertures 112.

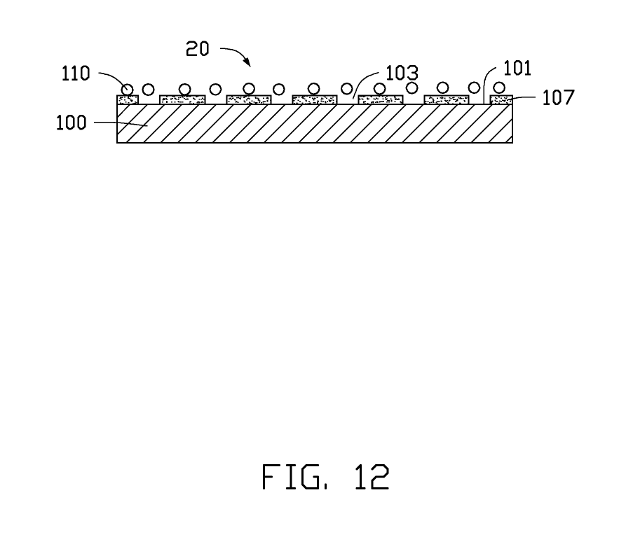

Referring to FIG. 12, an epitaxial substrate 20 includes a base 100 and a carbon nanotube layer 110. The base 100 includes an epitaxial growth surface 101 and a plurality of microstructures 107 located on it. The carbon nanotube layer 110 covers the microstructures 107 and is spaced from the epitaxial growth surface 101. The carbon nanotube layer 110 includes a first part and a second part. The first part covers and contacts the microstructure 107, and the second part, which is between each two adjacent microstructures 107, is suspended. The shape of microstructure 107 can be bar-shaped. The plurality of microstructures 107 can be parallel to or intersected with each other.

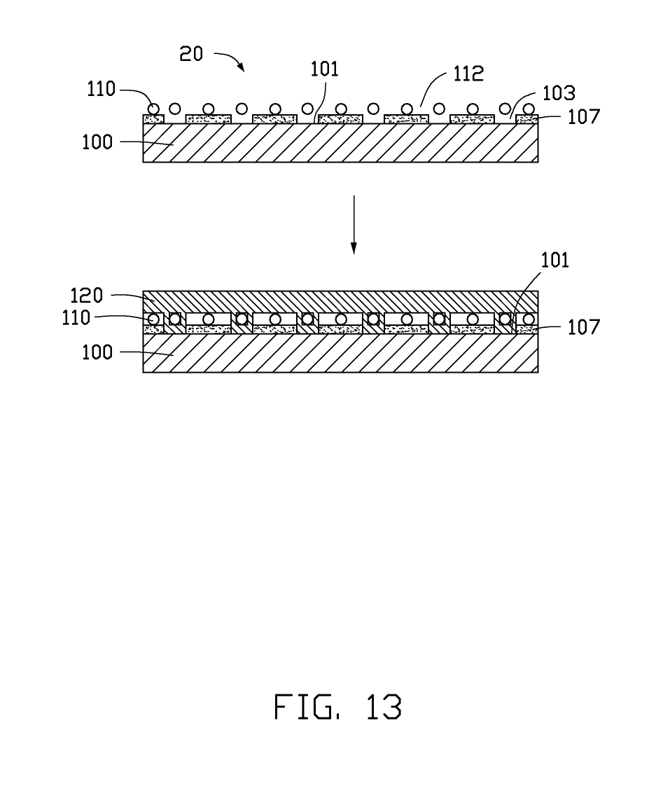

Referring to FIG. 13, a method for growing a epitaxial layer 120 on the epitaxial substrate 20 includes flowing steps:

(S24) providing a epitaxial substrate 20; and

(S25) growing the epitaxial layer 120 on the epitaxial substrate 20.

The method for growing the epitaxial layer 120 on the epitaxial substrate 20 is similar to that on the epitaxial substrate 10, except that the epitaxial substrate 20 includes a plurality of microstructures 107 on the epitaxial growth surface 101.

In step (S25), the epitaxial layer 120 grows from the exposed epitaxial growth surface 101 and up to through the apertures 112. The epitaxial layer 120 forms to an integrated structure and covers the entire carbon nanotube layer 110. In one embodiment, the material of the epitaxial layer is GaN, and the material of the microstructures 107 is silicon dioxide. The GaN cannot grow on the silicon dioxide. Thus while growing the epitaxial layer 120, the epitaxial layer 120 can only grow from the bottom of the grooves 103, and cannot grow from the top surface of the microstructures 107. The epitaxial crystal grains will grow in the grooves 103 and eventually the epitaxial crystal grains fill the grooves 103. After that, the growth direction of the epitaxial crystal grains can be parallel with the epitaxial growth surface 101. Thus the carbon nanotubes which are suspended between the two adjacent microstructures 107 will be enclosed in the epitaxial layer 120. Additionally, during the epitaxial crystal grains grow along a direction parallel with the epitaxial growth surface 101, the epitaxial crystal grains in the two adjacent grooves will be gradually combined. Thus the epitaxial layer 120 forms to an integrated structure, and the microstructures 107 and the carbon nanotube layer 110 are covered by the epitaxial layer 120.

It can be understood that, while the microstructures 107 can also support the growth of the epitaxial layer 120, the epitaxial crystal grains can grow both on the bottom of the grooves 103 and the top surface of the microstructures 107. The epitaxial layer 120 will grow from the grooves 103 and cover the whole microstructure 107.

The method for growing the epitaxial layer on the epitaxial substrate has following advantages. First, the epitaxial substrate is a patterned structure having a plurality of microstructures in micrometer scale, so the dislocation during the growth will be reduced. Second, the carbon nanotube layer is a patterned structure, the thickness and the aperture is in nanometer scale, thus the dislocation is further reduced and the quality of the epitaxial layer is improved. Third, due to the existence of the carbon nanotube layer, the contact surface between the epitaxial layer and the base will be reduced, and the stress between them is reduced, thus the epitaxial substrate can be used to grow a relatively thicker epitaxial layer. Fourth, the carbon nanotube layer is a freestanding structure, thus it can be directly placed on the base, and the method is simple and low in cost. Fifth, the epitaxial layer grown on the epitaxial substrate has relatively less dislocation, so it can be used to produce electronics in higher performance.

It is to be understood that the above-described embodiments are intended to illustrate rather than limit the disclosure. Any elements described in accordance with any embodiments is understood that they can be used in addition or substituted in other embodiments. Embodiments can also be used together. Variations may be made to the embodiments without departing from the spirit of the disclosure. The above-described embodiments illustrate the scope of the disclosure but do not restrict the scope of the disclosure.

Depending on the embodiment, certain of the steps of methods described may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

What is claimed is:

1. An epitaxial substrate comprising:
a base having a epitaxial growth surface and defining a plurality of grooves on the epitaxial growth surface; and
a carbon nanotube layer covering the epitaxial growth surface, wherein a portion of the carbon nanotube layer, that corresponds to the grooves, is suspended.

2. The epitaxial substrate of claim 1, wherein the plurality of grooves are extend from the epitaxial growth surface into the base.

3. The epitaxial substrate of claim 1, wherein the plurality of grooves is defined by a plurality of microstructures located on the epitaxial growth surface.

4. The epitaxial substrate of claim 1, wherein a width of each of the plurality of grooves ranges from about 1 μm to about 50 μm, a depth of each of the plurality of grooves ranges from about 0.1 μm to about 1 μm, and a interval between the two adjacent grooves ranges from about 1 μm to about 20 μm.

5. The epitaxial substrate of claim 1, wherein the carbon nanotube layer is a freestanding structure consist of a plurality of carbon nanotubes, and the carbon nanotube layer defines a plurality of apertures passing through the carbon nanotube layer along a direction of a thickness of the carbon nanotube layer.

6. The epitaxial substrate of claim 5, wherein a width of the aperture ranges from about 10 nm to about 500 μm.

7. The epitaxial substrate of claim 1, wherein the carbon nanotube layer comprises a plurality of carbon nanotubes extending along the same direction and joined end to end by van der Waals force, and an extending direction of the carbon nanotube layer is parallel to the epitaxial growth surface.

8. The epitaxial substrate of claim 7, wherein the plurality of grooves extends parallel to each other, and the extending direction of the carbon nanotube layer is perpendicular to that of the groove.

9. The epitaxial substrate of claim 1, wherein the carbon nanotube layer comprises a plurality of carbon nanotubes extending along a crystallographic orientation of the base.

10. A method for making an epitaxial substrate, the method comprising:
providing a base having an epitaxial growth surface;
patterning the epitaxial growth surface; and
placing a first carbon nanotube layer on the epitaxial growth surface.

11. The method of claim 10, wherein the epitaxial growth surface is patterned by etching the epitaxial growth surface or placing a plurality of microstructures on the epitaxial growth surface.

12. The method of claim 10, wherein the epitaxial growth surface is patterned by following steps:
placing a second carbon nanotube layer on the epitaxial growth surface, and the second carbon nanotube layer defines a plurality of apertures;
growing a plurality of microstructures through the plurality of apertures on the epitaxial growth surface; and
removing the second carbon nanotube layer from the epitaxial growth surface.

13. The method of claim 10, wherein the first carbon nanotube layer comprises a plurality of carbon nanotubes extending along a crystallographic orientation of the base.

14. A method for growing an epitaxial layer, the method comprising:
providing an epitaxial substrate, wherein the epitaxial substrate comprises a base having a patterned epitaxial growth surface and a carbon nanotube layer covering on the patterned epitaxial growth surface, wherein at least part of the carbon nanotube layer is suspended; and
growing the epitaxial layer on the patterned epitaxial growth surface.

15. The method of claim 14, wherein the patterned epitaxial growth surface is formed by etching a surface of the base to form a plurality of grooves, and the at least part of the carbon nanotube layer is suspended above the plurality of grooves.

16. The method of claim 15, wherein the carbon nanotube layer defines a plurality of apertures to expose part of the patterned epitaxial growth surface, and the epitaxial layer grows from the patterned epitaxial growth surface which is exposed through the plurality of apertures.

17. The method of claim 14, wherein the patterned epitaxial growth surface is formed by locating a plurality of microstructures on a surface of the base to define a plurality of grooves, and the at least part of the carbon nanotube layer is suspended above the plurality of grooves.

18. The method of claim 17, wherein the epitaxial layer grows from a bottom of the plurality of grooves and up to through apertures of the carbon nanotube layer.

19. The method of claim 18, wherein the epitaxial layer grows to cover the microstructures and the carbon nanotube layer.

20. The method of claim 14, wherein a plurality of holes is formed in the epitaxial layer and a plurality of carbon nanotubes of the carbon nanotube layer is embedded in the plurality of holes.
